(19) United States
(12) Patent Application Publication
(10) Pub. No.: US 2017/0179226 A1
(43) Pub. Date: Jun. 22, 2017

(54) ULTRASOUND T/R ISOLTATION DISOLATOR WITH FAST RECOVERY TIME ON SOI

(71) Applicant: Microchip Technology Incorporated, Chandler, AZ (US)

(72) Inventor: Hua Yang, San Jose, CA (US)

(73) Assignee: Microchip Technology Incorporated, Chandler, AZ (US)

(21) Appl. No.: 15/369,955

(22) Filed: Dec. 6, 2016

Related U.S. Application Data
(60) Provisional application No. 62/269,506, filed on Dec. 18, 2015.

(51) Int. Cl. H01L 29/06; H01L 21/84; H01L 27/12

(52) U.S. Cl. CPC H01L 29/0646; H01L 27/1203; H01L 29/0657; H01L 21/84

(57) ABSTRACT

A semiconductor disolator device is provided. The device may include a silicon-on-insulator (SOI) substrate, a body layer disposed on the SOI substrate, a first p-type well disposed on the body layer, a first n-type well disposed on the first p-type well to form a first p-n junction, and a second p-type well that is spaced a predetermined distance from at least one of the first p-type well and first n-type well.

### CROSS REFERENCE TO RELATED APPLICATION

This application claims the benefit of U.S. Provisional Patent Application No. 62/269,506, filed on Dec. 18, 2015, which is incorporated herein by reference in its entirety.

### TECHNICAL FIELD

The present disclosure relates generally to a disolator that may increase the forward current conducted by the device, while reducing capacitance and improving recovery time. Ultrasound transmission/receiver circuits often include diodes, bipolar junction transistors (BJTs), or silicon controlled rectifiers (SCRs) in order to pass large current and isolate the signal from noise within the circuit. Diode and BJT arrays employ multiple p-type and n-type electrodes. SCRs are solid-state current controlling devices that have four layers of alternating p-type and n-type semiconductor material (PNPN). However, diodes, BJTs, and SCRs typically use lightly doped n-type and p-type semiconductor materials, which limits the amount of forward current. In order to increase the amount of forward current, the n-type and p-type wells must be made larger, which is disadvantageous for many applications. In addition, the increased size causes the negative effect of increasing the capacitance.

Accordingly, it is desirable to find a solution that allows for increased forward current without increasing the size or the capacitance of the device, and that is fast and can be integrated in chip.

### SUMMARY

According to an aspect of one or more exemplary embodiments, there is provided an integrated disolator device that may achieve an increased forward current, maintain a fast reverse recovery time, but without increasing the size or capacitance of the device. The device according to one or more exemplary embodiments may include a silicon-on-insulator (SOI) substrate, a body layer disposed on the SOI substrate, a first p-type well disposed on the body layer, a first n-type well disposed on the first p-type well to form a first p-n junction, and a second p-type well that is spaced a predetermined distance from at least one of the first p-type well and the first n-type well.

The p-type well may be circular in shape and may surround the first p-type well and the first n-type well.

The first p-type well and the first n-type well may be circular in shape. The diameter of the first p-type well may be less than the diameter of the first n-type well. The diameter of the first p-type well may be approximately 3 microns, and the diameter of the first n-type well may be approximately 7 microns.

The first p-type well may have a vertical depth of approximately 0.5 microns, and the first n-type well may have a vertical depth of approximately 0.25 microns.

The second p-type well may be more heavily doped than the first p-type well. The second p-type well may have a doping concentration of approximately 2×10¹⁹/cm³, and the first p-type well may have a doping concentration of approximately 5×10¹⁸/cm³.

The first n-type well may be more heavily doped than the first p-type well. The first n-type well may have a doping concentration of approximately 2×10¹⁹/cm³, and the first p-type well may have a doping concentration of approximately 5×10¹⁸/cm³.

The doping concentration of the first p-type well may be approximately 2.5 times greater than a doping concentration of the body layer.

The first p-type well and the second p-type well may be spaced apart by approximately 3.5 microns. The distance from the first n-type well to the second p-type well may be approximately two microns.

The device according to one or more exemplary embodiments may also include a third p-type well disposed on the body layer and outside of the second p-type well and a second n-type well disposed on the third p-type well to form a second p-n junction. The second n-type well may be disposed outside of the second p-type well.

The second n-type well may be spaced approximately 7 microns from the first n-type well. The center point of the first n-type well may be spaced approximately 17 microns from the center point of the second n-type well.

### BRIEF DESCRIPTION OF DRAWINGS

FIG. 1 is a cross-sectional view of a disolator device according to an exemplary embodiment.

FIG. 2 is a top view of a disolator device according to an exemplary embodiment.

### DETAILED DESCRIPTION OF EXEMPLARY EMBODIMENTS

Reference will now be made in detail to the following exemplary embodiments, which are illustrated in the accompanying drawings, wherein like reference numerals refer to like elements throughout. The exemplary embodiments may be embodied in various forms without being limited to the exemplary embodiments set forth herein. Descriptions of well-known parts are omitted for clarity.

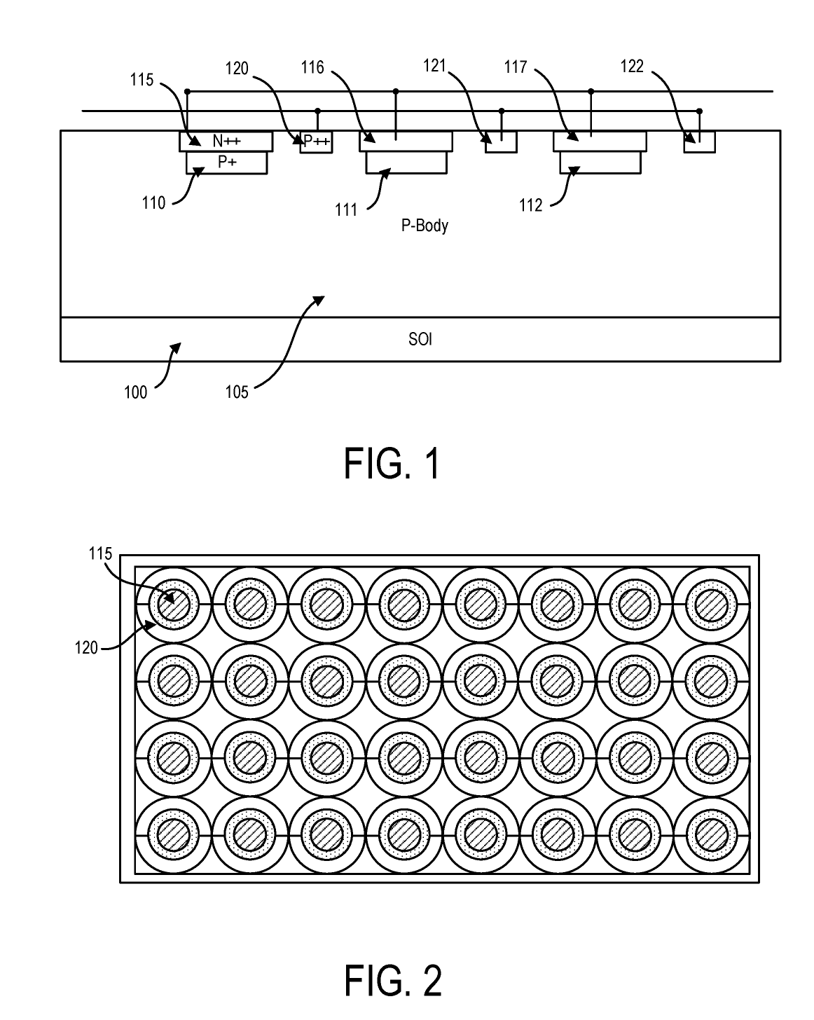

Although the components of FIGS. 1 and 2 discussed below are shown for explanatory purposes, the relative sizes of the components are not drawn to scale. Referring to FIG. 1, a device according to an exemplary embodiment may include a silicon-on-insulator (SOI) substrate 100, which may be made of an oxide, or other material such as sapphire. A p-type body layer 105 may be disposed on the SOI, and may include one or more p-type wells. In the exemplary embodiment of FIG. 1, the device includes three p-type wells 110, 111, and 112. The p-type wells 110, 111, and 112 may be more heavily doped than p-type body layer 105. For example, and without limitation, the three p-type wells 110, 111, and 112 may have a doping concentration of approximately 5×10¹⁸/cm³, and the p-type body layer 105 may have a doping concentration of approximately 2×10¹⁸/cm³, however other doping concentrations and relative doping concentrations may be used.

The device according to the exemplary embodiment of FIG. 1 may also include one or more n-type wells disposed on the p-type wells so as to form a P-N junction. According to the exemplary embodiment of FIG. 1, the device may include three n-type wells 115, 116, and 117 that form P-N junctions with p-type wells 110, 111, and 112, respectively. Each of the n-type wells 115, 116, and 117 may have a higher doping concentration than p-type wells 110, 111, and 112. For example, and without limitation, the three p-type wells 110, 111, and 112 may have a doping concentration of approximately 5×10¹⁸/cm³, and the three n-type wells 115, 116, and 117 may have a doping concentration of approximately 2×10¹⁹/cm³. The n-type wells 115, 116, and 117 may also have a greater cross-sectional length than the p-type wells 110, 111, and 112. According to the exemplary embodiment, the n-type wells 115, 116, and 117 may be circular in shape. The three p-type wells 110, 111, and 112 may also be circular in shape. The circular n-type wells 115, 116, and 117 may each have a diameter of approximately 7 μm and a vertical depth of approximately 0.25 μm, though other dimensions may be used as well. The circular p-type wells 110, 111, and 112 may have a diameter of approximately 3 μm, and a vertical depth of approximately 0.5 μm, though other dimensions may also be used.

The device according to the exemplary embodiment of FIG. 1 may also include one or more heavily doped p-type wells that are alternatingly disposed between the P-N junctions formed by the p-type wells 110, 111, and 112, and the n-type wells 115, 116, and 117. According to the exemplary embodiment of FIG. 1, the device may include three heavily doped p-type wells 120, 121, and 122. The heavily doped p-type wells 120, 121, and 122 may also be circular in shape. The heavily doped p-type wells may have a doping concentration of approximately 2×10¹⁹/cm³; however other doping concentrations may also be used. The heavily doped p-type wells 120, 121, and 122 may have a shorter cross-sectional length than the p-type wells 110, 111, and 112, and/or the n-type wells 115, 116, and 117. The heavily doped p-type wells 120, 121, and 122 may have a vertical depth of approximately 0.25 μm.

Each of the n-type wells 115, 116, and 117 may be spaced from the next adjacent n-type well by a predetermined distance. According to an exemplary embodiment, the two closest edges of two adjacent n-type wells may be spaced approximately 7 μm, however the exemplary embodiment is not limited to this spacing. According to an exemplary embodiment, there may be a spacing of approximately 17 μm from the center of one n-type well and the center of an adjacent n-type well. According to an exemplary embodiment, the closest edge of an n-type well may be spaced a predetermined distance from the adjacent heavily doped p-type well. For example, n-type well 115 and heavily doped p-type well 120 may be spaced so that the edge of the n-type well 115 closest to the heavily doped p-type well 120 is approximately 3.5 μm from the center of heavily doped p-type well 120. According to one or more exemplary embodiments, the edge of the n-type well 115 may be spaced approximately 2 μm from the closest edge of the heavily doped p-type well 120. In addition, a top surface of the n-type well 115 may be spaced less than 3 μm from a top surface of the SOI substrate 100, however the exemplary embodiment is not limited to this spacing. The top surface of n-type wells 116 and 117 may also be spaced less than 3 μm from the top surface of the SOI substrate 100.

In the device according to the exemplary embodiment of FIG. 1, an anode may be formed at the heavily doped p-type well 122, and a cathode may be formed at the n-type well 115. When a sufficient voltage is applied to the anode, the device becomes forward biased and conducts current from the anode to the cathode. Due to the P-N junctions created by the n-type wells and p-type wells, the current flowing from the heavily doped p-type wells to the n-type wells is generally near the surface of the device. In addition, the device according to one or more exemplary embodiments of the present disclosure may achieve increased forward current as compared to silicon controlled rectifiers due to the arrangement of the n-type wells and the heavily doped p-type wells, and the exemplary doping concentrations. Moreover, the doping concentrations and layout of the n-type wells and heavily doped p-type wells allow for increased forward current without increasing capacitance or the size of the device.

In addition, the reverse recovery time, or the time required to transition from the conducting state to the quiescent state, may also be reduced in one or more exemplary embodiments. In the related art, Beta radiation is used to reduce the reverse recovery time, however this process is expensive and adds to overall production costs. The device according to one or more of the exemplary embodiments may reduce the reverse recovery time due to defects from the SOI substrate, defects near the surface of the device, and the doping concentrations. Imperfections in the SOI layer and the surface of the device, and the large amount of current flowing near the surface of the device, cause recombination between carriers, and thus reduces the carrier life time. As the carrier life decreases, the reverse recovery time also decreases.

Although the inventive concepts of the present disclosure have been described and illustrated with respect to exemplary embodiments thereof, it is not limited to the exemplary embodiments disclosed herein and modifications may be made therein without departing from the scope of the inventive concepts.

What is claimed is:

1. A semiconductor device comprising:
a silicon-on-insulator (SOI) substrate;
a body layer disposed on the SOI substrate;
a first p-type well disposed on the body layer;
a first n-type well disposed on the first p-type well to form a first p-n junction; and
a second p-type well that is spaced a predetermined distance from at least one of the first p-type well and first n-type well.

2. The semiconductor device of claim 1, wherein the second p-type well is circular in shape and surrounds the first p-type well and the first n-type well.

3. The semiconductor device of claim 2, wherein the first p-type well and the first n-type well are circular in shape.

4. The semiconductor device of claim 3, wherein a diameter of the first p-type well is less than a diameter of the first n-type well.

5. The semiconductor device of claim 4, wherein the diameter of the first p-type well is approximately 3 microns, and the diameter of the first n-type well is approximately 7 microns.

6. The semiconductor device of claim 5, wherein the first p-type well has a vertical depth of approximately 0.5 microns, and the first n-type well has a vertical depth of approximately 0.25 microns.

7. The semiconductor device of claim 1, wherein the second p-type well is more heavily doped than the first p-type well.

8. The semiconductor device of claim 7, wherein the second p-type well has a doping concentration of approximately 2×10¹⁹/cm³, and the first p-type well has a doping concentration of approximately 5×10¹⁸/cm³.

9. The semiconductor device of claim 1, wherein the first n-type well is more heavily doped than the first p-type well.

10. The semiconductor device of claim 9, wherein the first n-type well has a doping concentration of approximately 2×10¹⁹/cm³, and the first p-type well has a doping concentration of approximately 5×10¹⁸/cm³.

11. The semiconductor device of claim 1 wherein a doping concentration of the first p-type well is approximately 2.5 times greater than a doping concentration of the body layer.

12. The semiconductor device of claim 1, wherein the first p-type well and the second p-type well are spaced apart by approximately 3.5 microns.

13. The semiconductor device of claim 1, wherein the distance from the first n-type well to the second p-type well is approximately two microns.

14. The semiconductor device of claim 1, further comprising:
a third p-type well disposed on the body layer and outside of the second p-type well;
a second n-type well disposed on the third p-type well to form a second p-n junction;
wherein the second n-type well is disposed outside of the second p-type well.

15. The semiconductor device of claim 14, wherein the second n-type well is spaced approximately 7 microns from the first n-type well.

16. The semiconductor device of claim 14, wherein a center point of the first n-type well is spaced approximately 17 microns from a center point of the second n-type well.

17. The semiconductor device of claim 1, wherein a top surface of the first n-type well is disposed less than 3 microns from a top surface of the SOI substrate.
